(19) United States
(12) Patent Application Publication
(10) Pub. No.: US 2026/0293203 A1
(43) Pub. Date: Sep. 24, 2026

(54) SEMICONDUCTOR DEVICE AND SEMICONDUCTOR STORAGE DEVICE

(71) Applicant: Kioxia Corporation, Tokyo (JP)

(72) Inventors: Kohei KAWAGUCHI, Yokkaichi Mie (JP); Kenichi HAGA, Yokkaichi Mie (JP); Takamasa HAMAI, Yokkaichi Mie (JP); Tatsuki KIKUCHI, Yokkaichi Mie (JP); Akinori KAMIYAMA, Yokkaichi Mie (JP); Satoshi HASEGAWA, Inabe Mie (JP); Keiji IKEDA, Yokkaichi Mie (JP); Yuya MATSUZAWA, Moriya Ibaraki (JP)

(21) Appl. No.: 19/329,080

(22) Filed: Sep. 15, 2025

(30) Foreign Application Priority Data
Mar. 21, 2025 (JP) 2025-046980

(51) Int. Cl. H10D 30/67; H10B 12/00; H10D 30/01; H10D 62/60

(52) U.S. Cl. CPC H10D 30/6728; H10B 12/33; H10D 30/0312; H10D 30/0318; H10D 30/6735; H10D 30/6737; H10D 30/6756; H10D 30/6757; H10D 62/60

(57) ABSTRACT

According to one embodiment, a semiconductor device includes an oxide semiconductor layer extending in an up-down direction. The oxide semiconductor layer has an annular upper surface with a recessed interior surface below the annular upper surface. The recessed interior surface is surrounded by an inner edge of the annular upper surface. A bottom surface of the oxide semiconductor layer is at an opposite end in the up-down direction. An outer peripheral surface extends from the upper surface to the bottom surface of the oxide semiconductor layer. An insulating film surrounds the side surface from the upper to bottom surface. A first electrode contacts the bottom surface. A gate electrode faces the oxide semiconductor layer with the insulating film interposed therebetween. A second electrode contacts the annular upper surface and the recessed interior surface of the oxide semiconductor layer.

### CROSS-REFERENCE TO RELATED APPLICATION

This application is based upon and claims the benefit of priority from Japanese Patent Application No. 2025-046980, filed Mar. 21, 2025, the entire contents of which are incorporated herein by reference.

### FIELD

Embodiments described herein relate generally to a semiconductor device and a semiconductor storage device.

### BACKGROUND

Some semiconductor elements can be formed of an oxide semiconductor material. There is a demand for improving the performance of a semiconductor device by appropriately connecting a oxide-type semiconductor layer to an electrode.

### BRIEF DESCRIPTION OF THE DRAWINGS

FIG. 1 is a circuit diagram showing an example of a circuit configuration of a memory cell array according to a first embodiment.

FIG. 2 is a schematic cross-sectional view showing a structural example of a semiconductor storage device according to the first embodiment.

FIG. 3 is a detailed cross-sectional view of a semiconductor device.

FIG. 4 is an enlarged cross-sectional view of an upper part of a semiconductor device.

FIG. 5 is a view showing an example of the distribution of electron density in a thin portion.

FIG. 6-11 depict aspects of a manufacturing process of a semiconductor device of a first embodiment.

FIG. 12 is an enlarged cross-sectional view of an upper part of a semiconductor device.

FIG. 13 is a view showing an example of a change in normalized contact resistance with respect to the depth of a hole portion.

FIG. 14 is an enlarged cross-sectional view of an upper part of a semiconductor device.

FIG. 15 is an enlarged cross-sectional view of an upper part of a semiconductor device.

FIG. 16 is an enlarged cross-sectional view of an upper part of a semiconductor device.

FIG. 17 is an enlarged cross-sectional view of an upper part of a semiconductor device.

FIG. 18 is a cross-sectional view parallel to the YZ plane showing a manufacturing process of a semiconductor device of a sixth embodiment.

FIG. 19-23 depict aspects of a manufacturing process of a semiconductor device of a sixth embodiment.

FIG. 24 is an enlarged cross-sectional view of the upper part of a semiconductor device as viewed at the cross section provided in the oxide semiconductor layer.

### DETAILED DESCRIPTION

Embodiments provide a semiconductor device and a semiconductor storage device having high performance semiconductor.

In general, according to one embodiment, a semiconductor device, comprising includes an oxide semiconductor layer extending in an up-down direction, the oxide semiconductor layer having: an annular upper surface with a recessed interior surface below the annular upper surface, the recessed interior surface being surrounded by an inner edge of the annular upper surface; a bottom surface at an opposite end of the annular upper surface in the up-down direction; and an outer peripheral side surface extending from the annular upper surface to the bottom surface. An insulating film surrounds the outer peripheral side surface of the oxide semiconductor layer from the annular upper surface to bottom surface. A first electrode is in contact with the bottom surface of the oxide semiconductor layer. A gate electrode faces a part of the outer peripheral side surface with the insulating film interposed therebetween. The part is spaced from the annular upper surface and the bottom surface of the oxide semiconductor layer. A second electrode is in contact with the annular upper surface and the recessed interior surface of the oxide semiconductor layer.

According to an embodiment, a semiconductor storage device includes a semiconductor device, a first capacitor electrode that is connected to a first electrode or a second electrode, a second capacitor electrode that faces the first capacitor electrode, and a dielectric film that is provided between the first capacitor electrode and the second capacitor electrode.

Hereinafter, the certain example embodiments will be described with reference to the drawings. In order to facilitate understanding of the description, the same elements, components, aspects, and the like are designated by the same reference symbols in each drawing, and duplicate description may be omitted.

Drawings may show an X-axis, a Y-axis, and a Z-axis. The X-axis, the Y-axis, and the Z-axis form a three-dimensional right-handed orthogonal coordinate system. The arrow direction of the X-axis may be referred to as an +X-axis direction, and the opposite direction may be referred to as an −X-axis direction, and similar nomenclature applies to other axes. A +Z-axis direction and a −Z-axis direction may also be referred to as an “upper side” and a “lower side”, respectively. In addition, a plane orthogonal to the X-axis, the Y-axis, or the Z-axis may be referred to as a YZ plane, a ZX plane, or an XY plane. In addition, a Z-axis direction may be referred to as an “up-down direction”. The terms “upper side”, “lower side”, and “up-down direction” are terms indicating a relative positional relationship in the drawings, and are not terms for determining an orientation based on a vertical gravitational direction or the like.

Further, unless otherwise specified, the dimensions or the like of the components shown in each drawing may be shown differently from actual dimensions in order to facilitate understanding of the description.

In the present specification, the term “connection” includes not only a physical connection but also an electrical connection, and includes not only a direct connection but also an indirect connection, unless otherwise specified.

In the present specification, the term “formed on the upper side” includes not only when something is formed in direct contact with the upper side but also when formed on the upper side with something interposed therebetween, unless otherwise specified. The same also applies to a case of “formed on the lower side” or the like.

### First Embodiment

A semiconductor storage device 101 according to a first embodiment is a DRAM provided with vertical memory transistors and includes a memory cell array.

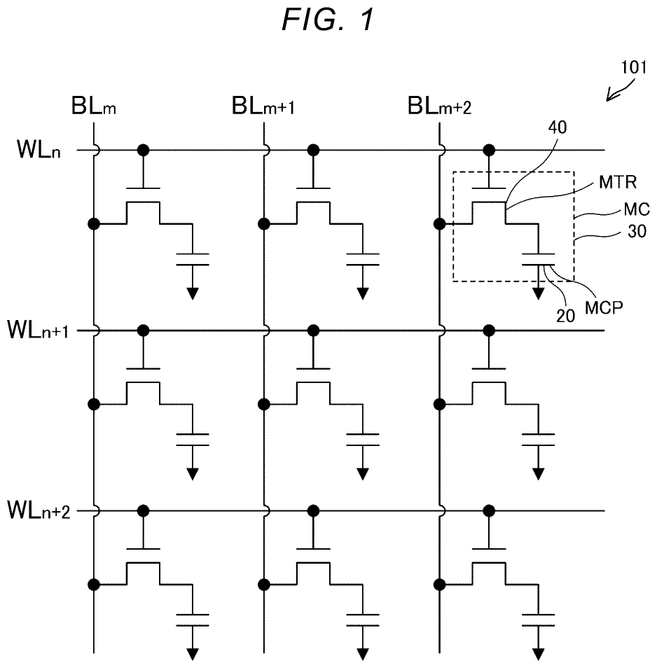

As shown in FIG. 1, the memory cell array is provided with a plurality of memory cells MC, a plurality of word lines WL, and a plurality of bit lines BL.

In FIG. 1, as an example of a plurality of word lines WL, a word line WLₙ, a word line WLₙ₊₁, and a word line WLₙ₊₂ are shown (here, n is a positive integer). In addition, in FIG. 1, as an example of a plurality of bit lines BL, a bit line BLₘ, a bit line BLₘ₊₁, and a bit line BLₘ₊₂ are shown (here, m is a positive integer). The number of memory cells MC is not limited to the number shown in FIG. 1.

The plurality of memory cells MC are arranged in a matrix shape and form a memory cell array. Each memory cell MC is provided with a memory transistor MTR, which is a field effect transistor (FET), and a memory capacitor MCP.

The series of memory cells MC provided adjacent in a row direction are connected to the same word line WL (for example, the word line WLₙ) corresponding to the row (for example, an n-th row) to which the memory cells MC belong. The series of memory cells MC provided adjacent in a column direction are connected to the same bit line BL (for example, the bit line BLₘ₊₂) corresponding to the column (for example, an m+2-th column) to which the memory cells MC belong.

Specifically, the gate of the memory transistor MTR provided in the memory cell MC is connected to the word line WL corresponding to the row to which the memory cell MC belongs. One of the source or the drain of the memory transistor MTR is connected to the bit line BL corresponding to the column to which the memory cell MC belongs.

One electrode of the memory capacitor MCP provided in the memory cell MC is connected to the other of the source or the drain of the memory transistor MTR provided in the memory cell MC. The other electrode of the memory cell MC is connected to a power supply line that supplies a specific voltage.

The memory cell MC is configured to store data by accumulating charges in the memory capacitor MCP by a current flowing in the corresponding bit line BL according to switching (ON/OFF) of the memory transistor MTR based on the voltage on the corresponding word line WL.

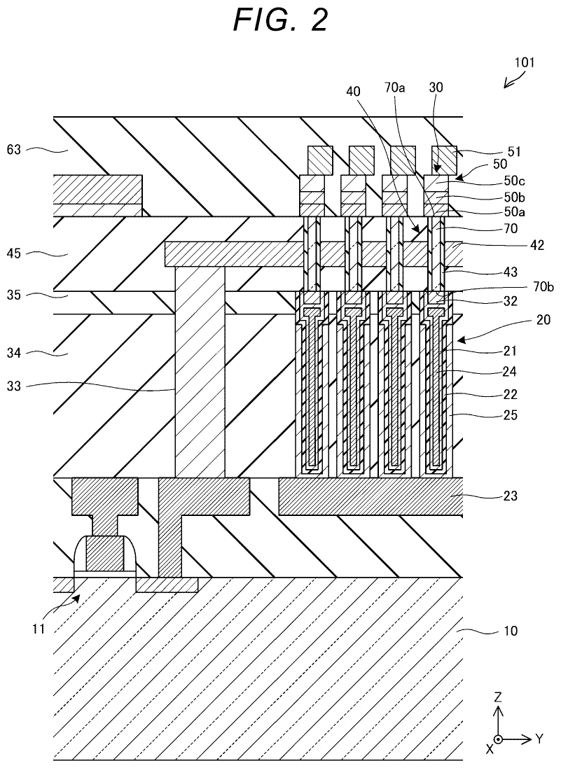

As shown in FIG. 2, the semiconductor storage device 101 is provided with a semiconductor substrate 10, a circuit 11 (an example of a “semiconductor circuit”), a capacitor 20, a semiconductor device 30, a conductor 33, and insulating layers 34, 35, and 63.

The capacitor 20 includes an insulating film 22 (an example of a “dielectric film”), a conductor 23, a capacitor electrode 24 (an example of a “first capacitor electrode”), and a capacitor electrode 25 (an example of a “second capacitor electrode”).

The semiconductor device 30 includes a field effect transistor 40 (an example of a “semiconductor element”), an upper electrode 50 provided on the upper side of the field effect transistor 40, a lower electrode 32 provided on the lower side of the field effect transistor 40, and a conductive layer 51 (an example of a “bit electrode”).

The field effect transistor 40 is provided with an oxide semiconductor layer 70 (an example of an “oxide semiconductor”), a gate insulating film 43, a conductive layer 42 (an example of a “gate electrode”), and an insulating layer 45. In this context, the field effect transistor 40 corresponds to the memory transistor MTR of the memory cell MC (refer to FIG. 1).

The oxide semiconductor layer 70 is formed in the insulating layer 45 and has an upper end 70a and a lower end 70b. The oxide semiconductor layer 70 is a columnar shape body extending in the up-down direction in the drawing. The oxide semiconductor layer 70 forms a channel of the field effect transistor 40. The oxide semiconductor layer 70 has an amorphous structure.

The oxide semiconductor layer 70 is a semiconductor in which oxygen deficiency acts as a donor. The oxide semiconductor layer 70 comprises oxygen and at least one of indium (In), gallium (Ga), aluminum (Al), zinc (Zn), tin (Sn), titanium (Ti), tungsten (W), molybdenum (Mo), iridium (Ir), or ruthenium (Ru). Additionally, the oxide semiconductor layer 70 may be formed from a type of channel material other than an oxide semiconductor. For example, it may be constituted by a material containing any of single-crystal silicon (c-Si), polycrystalline silicon (poly-Si), amorphous silicon (a-Si), impurity-doped silicon, silicon germanium (SiGe), or germanium (Ge).

In the present embodiment, the oxide semiconductor layer 70 comprises indium, zinc, and gallium as metal elements. Specifically, the oxide semiconductor layer 70 is an oxide of indium, gallium, and zinc such as InGaZnO (IGZO). The oxide semiconductor layer 70 may be another type of oxide semiconductor in other examples.

The field effect transistor 40 is a so-called vertical transistor having a channel extending in the Z-axis direction (up-down direction) substantially perpendicular to the surface of the semiconductor substrate 10.

The upper electrode 50 is formed on the upper side of the oxide semiconductor layer 70 and is connected to the upper end 70a of the oxide semiconductor layer 70.

The conductive layer 51 connects to the upper end 70a of the oxide semiconductor layer 70 through the upper electrode 50. The conductive layer 51 comprises, for example, tungsten (W).

The conductive layer 51 extends along an X-axis direction above the conductive layer 42. A plurality of conductive layers 51 are provided. The plurality of conductive layers 51 are repeatedly provided in an Y-axis direction. The plurality of conductive layers 51 are spaced apart from each other in the Y-axis direction. The conductive layer 51 corresponds to the bit line BL (see FIG. 1). In the present embodiment, the width of the conductive layer 51 in the Y-axis direction is substantially constant.

The lower electrode 32 is in contact with the lower end 70b of the oxide semiconductor layer 70. The lower electrode 32 comprises a conductive oxide. Specifically, the lower electrode 32 is formed of a metal oxide of, for example, indium and tin as metal elements. In the present embodiment, the lower electrode 32 is formed of indium-tin-oxide (ITO).

The circuit 11 configures a peripheral circuit such as a decoder for selecting a predetermined memory cell MC, a sense amplifier connected to the bit line BL, and a register configured with an SRAM, among the plurality of memory cells MC of the semiconductor storage device 101, that is, the capacitor 20 and the field effect transistor 40. The circuit 11 may be provided with a CMOS circuit having a field effect transistor of a P-channel type field effect transistor (Pch-FET) and an N-channel type field effect transistor (Nch-FET), which are formed by a CMOS process.

The field effect transistor of the circuit 11 may be formed using the semiconductor substrate 10, which may be, for example, a single crystal silicon substrate (monocrystalline silicon). The Pch-FET and the Nch-FET are so-called horizontal field effect transistors having a channel region, a source region, and a drain region in the semiconductor substrate 10, and having a channel for causing a carrier to flow in the X-axis direction or the Y-axis direction substantially parallel to the surface of the semiconductor substrate 10 in a region close to the surface of the semiconductor substrate 10. The semiconductor substrate 10 may have a conductive type of P-type or N-type. For convenience, FIG. 2 shows an example of a field effect transistor of the circuit 11.

The capacitor 20 is the memory capacitor MCP provided in the memory cell MC (refer to FIG. 1). Although the four capacitors 20 are shown in FIG. 2, the number of the capacitors 20 is not limited to four.

In the present embodiment, the capacitor 20 is provided on the upper side of the semiconductor substrate 10. The capacitor electrode 24 in the capacitor 20 is connected to the lower electrode 32 through a conductor 21. The capacitor electrode 25 faces the capacitor electrode 24. The insulating film 22 is provided between the capacitor electrode 24 and the capacitor electrode 25.

The capacitor 20 is a three-dimensional capacitor such as a pillar-type capacitor. In other examples, the capacitor of the present embodiment may be another capacitor configuration capable of accumulating charges and, in general, any capacitor configuration may be adopted.

In the present example, the capacitor electrode 24 is located below the lower electrode 32. The capacitor electrode 24 has an upper end facing the end surface of the lower electrode 32 on the lower side with the conductor 21 interposed therebetween. The capacitor electrode 24 has a columnar shape extending downward from the upper end. The conductor 21 covers the lower electrode 32 and the capacitor electrode 24. The insulating film 22 covers the conductor 21. The capacitor electrode 25 has a lower end that surrounds a part of the insulating film 22 on the lower side and is in contact with an end surface of the conductor 23 on the upper side.

The capacitor electrode 24 may comprise a material such as SiGe. The insulating film 22 may comprise a material such as ZrAlO. The conductor 21 may include materials such as tungsten or titanium nitride, and may also include materials such as amorphous silicon. Additionally, it may include metal oxides such as InO, ITO, or RuO. The conductor 23 and the capacitor electrode 25 may comprise a material such as tungsten or titanium nitride.

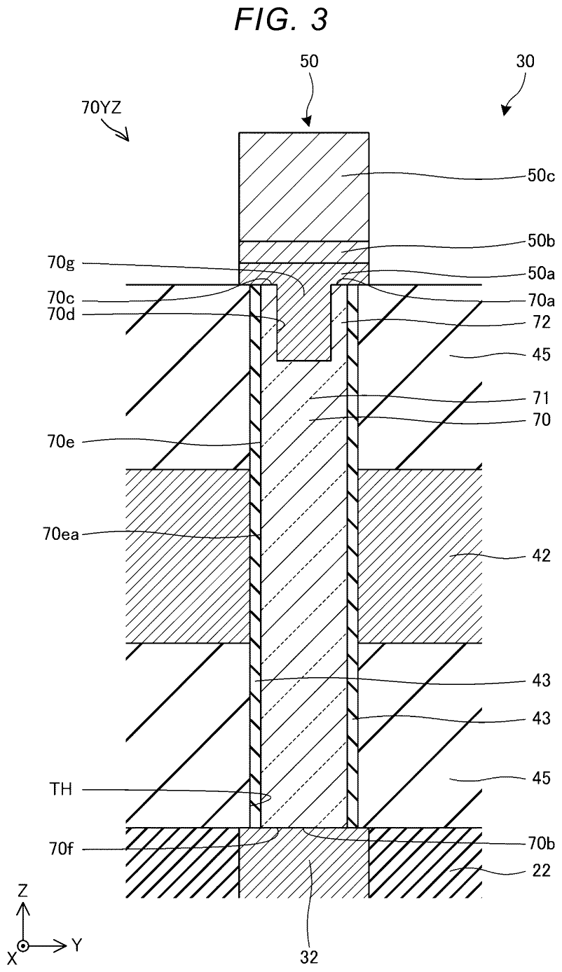

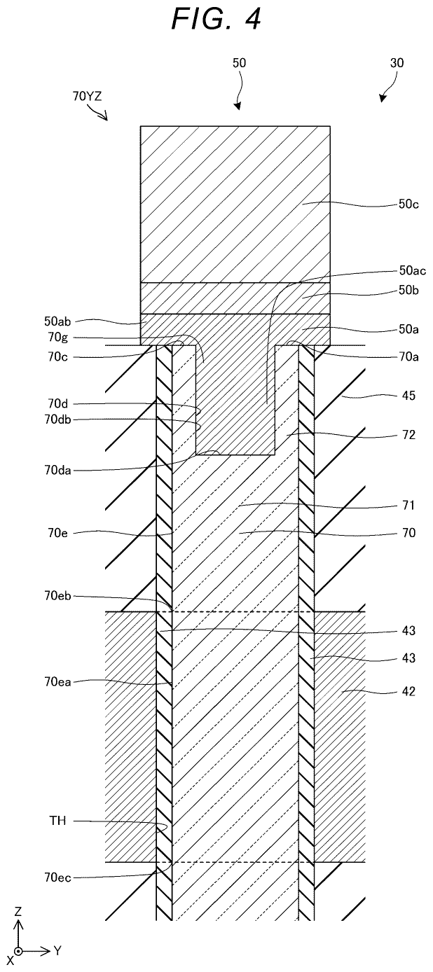

FIG. 3 is a cross-sectional view of the semiconductor device 30 as viewed at a cross section 70YZ parallel to a YZ plane and provided in the oxide semiconductor layer 70. FIG. 4 is an enlarged cross-sectional view of the upper part of the semiconductor device 30 as viewed at the cross section 70YZ provided in the oxide semiconductor layer 70.

As shown in FIGS. 3 and 4, the oxide semiconductor layer 70 has an upper surface 70c including the upper end 70a, a recessed surface 70d, a side surface 70e, and a lower surface 70f (an example of a “contact surface”) located below.

Specifically, the upper surface 70c has an annular shape when viewed from above the oxide semiconductor layer 70. Specifically, the upper surface 70c is a surface substantially parallel to the XY plane. The upper surface 70c has, for example, an annular shape or an elongated annular shape when viewed from above the oxide semiconductor layer 70.

The recessed surface 70d is in contact with an inner edge of the upper surface 70c. In other words, the recessed surface 70d is surrounded by the upper surface 70c when viewed from above the oxide semiconductor layer 70. The recessed surface 70d is recessed downward. That is, the hole portion 70g surrounded by the upper surface 70c is formed in the oxide semiconductor layer 70. The hole portion 70g is a non-penetrating hole dug downward.

In the present embodiment, the recessed surface 70d includes a bottom surface 70da and a cylindrical surface 70db. The bottom surface 70da is located on a lower side and is a substantially flat surface. The bottom surface 70da has, for example, a shape of a circle or an ellipse and is a surface substantially parallel to the XY plane. The bottom surface 70da is a bottom of the hole portion 70g.

The cylindrical surface 70db extends upward from the edge of the bottom surface 70da. Specifically, the cylindrical surface 70db is an inner wall surface of the hole portion 70g having, for example, a cross section of a circle or an ellipse.

The lower surface 70f includes the lower end 70b. The lower surface 70f is, for example, a surface substantially parallel to the XY plane and has a shape of a circular or an ellipse. The lower surface 70f is in contact with the surface of the lower electrode 32 on the upper side.

The side surface 70e is a surface substantially parallel to the Z-axis. The upper side of the side surface 70e is connected to the outer edge of the upper surface 70c. The lower side of the side surface 70e is connected to the outer edge of the lower surface 70f. Above the oxide semiconductor layer 70, the side surface 70e and the cylindrical surface 70db face each other. Hereinafter, a part of the oxide semiconductor layer 70 between the side surface 70e and the cylindrical surface 70db may be referred to as a thin portion 72. The distance between the side surface 70e and the cylindrical surface 70db is, for example, less than or equal to 5 nm. In other words, the thickness of the thin portion 72 is less than or equal to 5 nm.

The gate insulating film 43 surrounds the side surface 70e of the oxide semiconductor layer 70. Specifically, the gate insulating film 43 may comprise, for example, a silicon nitride film (Si₃N₄) or a silicon oxide film (SiO₂). The gate insulating film may also be, for example, hafnium oxide (HfO₂), zirconium oxide (ZrO₂), aluminum oxide (Al₂O₃), or a mixture thereof (such as HfZrO₂, HfAlO, ZrAlO) or a laminate thereof. The gate insulating film 43 covers the side surface 70e of the oxide semiconductor layer 70 over the entire circumference.

The conductive layer 42 (an example of a “gate electrode”) faces a part of the side surface 70e (hereinafter, this part may be referred to as a facing surface 70ea) that is spaced apart from the lower end 70b. The gate insulating film 43 is interposed therebetween the conductive layer 42 and the oxide semiconductor layer 70. The part of the oxide semiconductor layer 70 above the facing surface 70ea may be referred to as an extension portion 71. The extension portion 71 is above an end portion 70eb.

Specifically, the conductive layer 42 functions as a gate electrode of the field effect transistor 40 and surrounds the oxide semiconductor layer 70 with the gate insulating film 43 interposed therebetween at position between the upper end 70a and the lower end 70b of the oxide semiconductor layer 70. The conductive layer 42 contains, for example, tungsten (W) or titanium nitride (TiN). The conductive layer 42 may also be, for example, ruthenium (Ru) or molybdenum (Mo).

A lower end of the recessed surface 70d (that is, the end meeting the bottom surface 70da) is located above an end portion 70ec of the facing surface 70ea. In the present embodiment, the bottom surface 70da is located above the end portion 70eb of the facing surface 70ea.

The conductive layer 42 surrounds each of a plurality of oxide semiconductor layers 70 provided along the Y-axis direction with a plurality of gate insulating films 43 interposed therebetween.

A plurality of conductive layers 42 are provided. The plurality of conductive layers 42 are repeatedly provided in the X-axis direction. The plurality of conductive layers 42 are spaced apart from each other in the X-axis direction. The insulating layer 45 is provided on the upper side and the lower side of the conductive layer 42 and between conductive layers 42. That is, the conductive layers 42 adjacent to each other (neighboring one another) are separated from each other by a part of the insulating layer 45. The insulating layer 45 comprises, for example, silicon and oxygen. The conductive layer 42 corresponds to the word line WL (see FIG. 1).

The upper electrode 50 (an example of a “second electrode”) is in contact with the recessed surface 70d and the upper surface 70c of the oxide semiconductor layer 70. In the present embodiment, the upper electrode 50 includes a metal oxide layer 50a (an example of a “first conductive layer”), a barrier metal layer 50b (an example of a “second conductive layer”), and a metal film 50c (an example of a “third conductive layer”).

The metal oxide layer 50a in the upper electrode 50 comprises a conductive oxide. Specifically, the metal oxide layer 50a is a metal oxide including indium and tin as metal elements. More specifically, the metal oxide layer 50a is formed of indium-tin-oxide (ITO).

The lower electrode 32 and the metal oxide layer 50a are not limited to being or including ITO, and may comprise at least one element of indium, tin, zinc, cadmium, gold, silver, platinum, lead, copper, nickel, tungsten, and iron. The lower electrode 32 may be made of a conductive material that is not a metal oxide. For example, it may include tungsten (W), titanium (Ti), tantalum (Ta), ruthenium (Ru), iridium (Ir), or their nitrides or carbides. In addition, materials commonly used for wiring or electrode materials in semiconductor products, such as aluminum (Al), copper (Cu), cobalt (Co), platinum (Pt), and their alloys, may also be employed.

The metal oxide layer 50a is provided on the upper side of the oxide semiconductor layer 70. The metal oxide layer 50a includes a thin film-like thin film portion 50ab that extends along the XY plane and a protruding portion 50ac that completely fills the hole portion 70g in the oxide semiconductor layer 70 and protrudes downward from the thin film portion 50ab.

A surface of the protruding portion 50ac is in contact with the recessed surface 70d of the oxide semiconductor layer 70. A part of the surface of the thin film portion 50ab on the lower side is in contact with the upper surface 70c of the oxide semiconductor layer 70. The entire surface of the thin film portion 50ab on the lower side may be in contact with the upper surface 70c of the oxide semiconductor layer 70.

The barrier metal layer 50b is stacked on the metal oxide layer 50a. In the present embodiment, the barrier metal layer 50b has a thin film shape that extends along the XY plane.

The barrier metal layer 50b comprises titanium, oxygen, and nitrogen. Specifically, the barrier metal layer 50b is a stacked structure of titanium oxide (TiO₂) and titanium nitride (TiN).

The barrier metal layer 50b may be formed of titanium oxide nitride (TiON) in some examples. In addition, the barrier metal layer 50b may comprise titanium and one of oxygen and nitrogen. The barrier metal layer 50b may include a metal element other than titanium. Specifically, the barrier metal layer 50b may comprise tungsten, for example.

The metal film 50c is stacked on the metal oxide layer 50a. In the present embodiment, the metal film 50c has a thin film shape extending along the XY plane. The metal film 50c comprises, for example, tungsten.

### Effect

As described above, by forming the upper surface 70c and the recessed surface 70d above the oxide semiconductor layer 70, the area of the surface in contact with the oxide semiconductor layer 70 and the upper electrode 50 can be increased as compared with a configuration in which the surface of the oxide semiconductor layer 70 on the upper side is simply a flat surface. As a result, the parasitic resistance can be reduced, and thus the current flowing through the oxide semiconductor layer 70 can be increased.

When the semiconductor device 30 is in an on-state, the extension portion 71 is not surrounded by the conductive layer 42, but an electric field (referred to as a fringe electric field) based on the voltage of the conductive layer 42 is generated. The fringe electric field is weaker than the electric field in the region surrounded by the conductive layer 42.

The fringe electric field becomes weaker as the extension portion 71 is spaced farther apart from the conductive layer 42. In a region where the fringe electric field is weak, the resistance is high even in the on-state.

In the present embodiment, the hole portion 70g is formed in the oxide semiconductor layer 70, and the protruding portion 50ac of the metal oxide layer 50a is in the hole portion 70g so that the high-resistance oxide semiconductor layer 70 is replaced with the protruding portion 50ac having a low electric resistance, and the electric resistance of the extension portion 71 can be reduced. Thereby, the current flowing through the oxide semiconductor layer 70 can be increased.

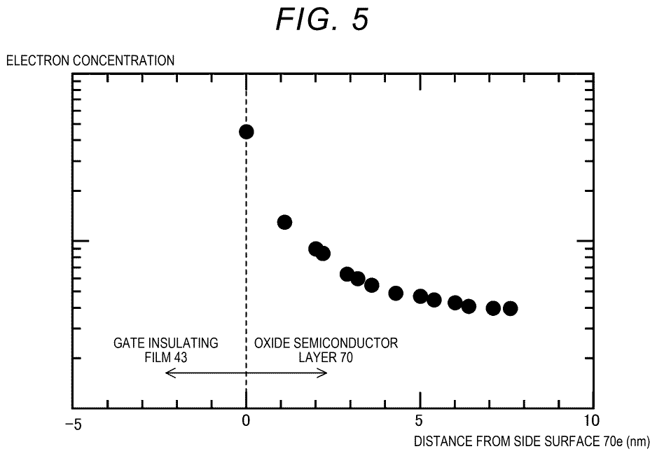

FIG. 5 is a view showing an example of the distribution of electron density in the thin portion 72. The vertical axis indicates an electron density represented by a logarithmic scale. The horizontal axis indicates a distance from the side surface 70e in units of “nm”. The distance is defined as positive in a direction approaching the cylindrical surface 70db from the side surface 70e.

As shown in FIG. 5, the electron density in the thin portion 72 is reduced as the distance from the side surface 70e increases by the fringe electric field when the semiconductor device 30 is in an on-state, and the electron density is sufficiently large in the range of 0 to 5 nm.

In the present embodiment, since the distance between the side surface 70e and the cylindrical surface 70db is less than or equal to 5 nm, a sufficient carrier can be generated in the thin portion 72, and thus the thin portion 72 can be used as a charge storage layer. Since the metal oxide layer 50a and the charge storage layer are in contact with each other, the interface resistance can be reduced, and thus the current flowing through the oxide semiconductor layer 70 can be increased.

### Method for Manufacturing Semiconductor Device 30

A method for manufacturing the semiconductor device 30 will be described as an example of a manufacturing method for a semiconductor device according to the first embodiment.

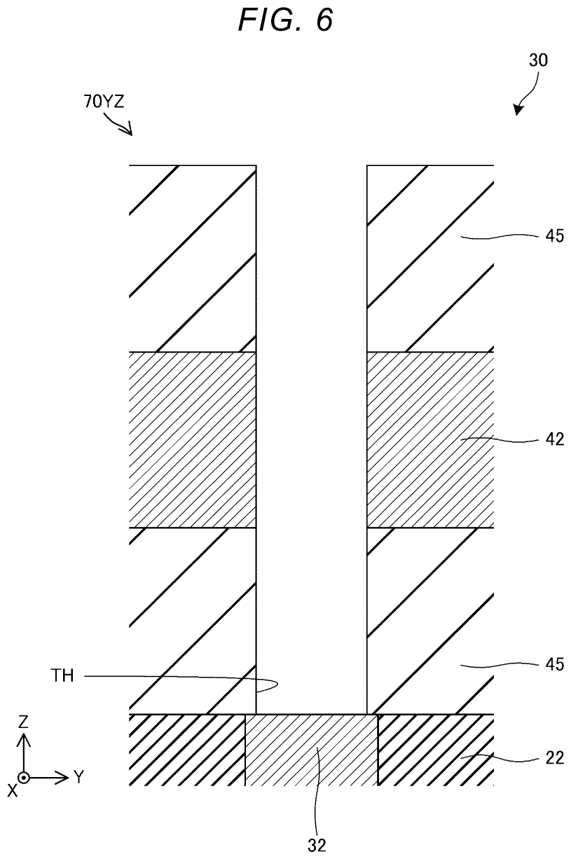

First, as shown in FIG. 6, a transistor hole TH is formed by reactive ion etching, and then is cleaned. The transistor hole TH extends substantially parallel to the Z-axis and penetrates the insulating layer 45 and the conductive layer 42. The lower electrode 32 is exposed at the bottom portion of the transistor hole TH.

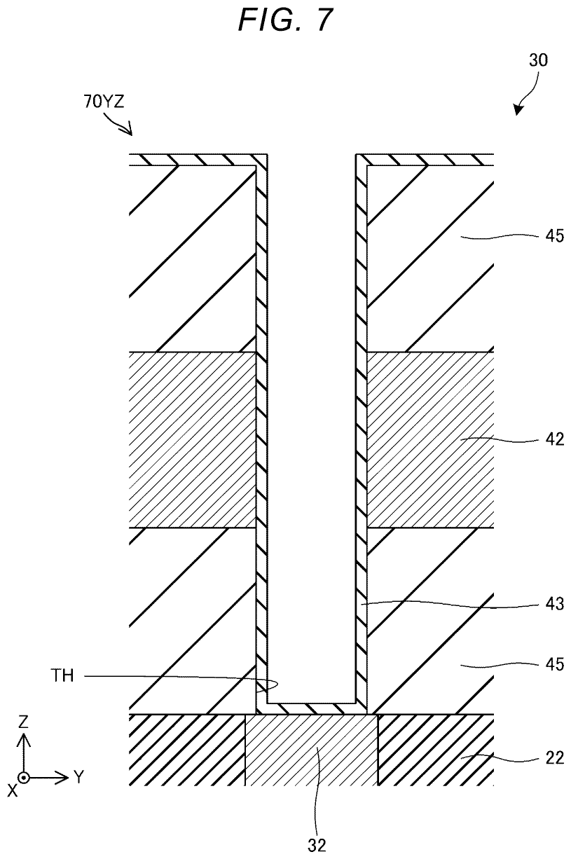

Next, as shown in FIG. 7, the gate insulating film 43 is formed on the inner wall surface and the bottom surface of the transistor hole TH and on the surface of the insulating layer 45 on the upper side.

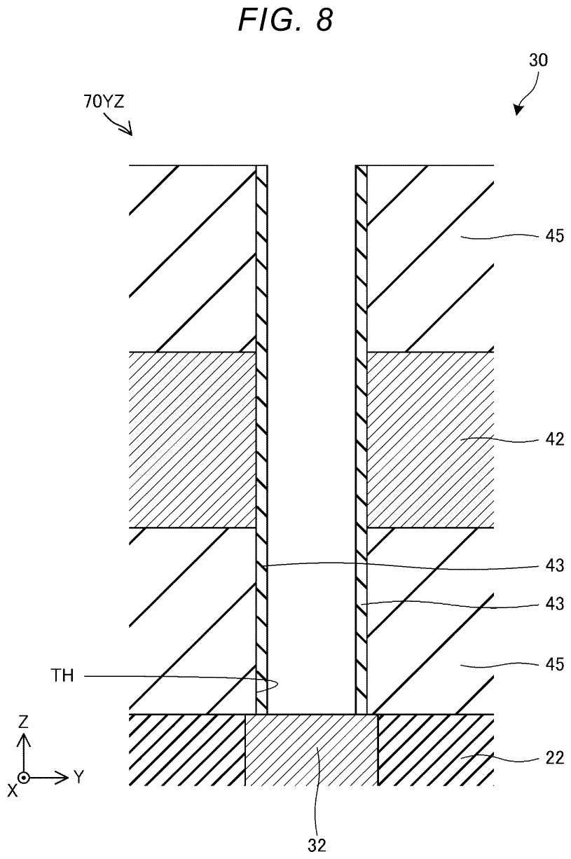

Next, as shown in FIG. 8, a part of the gate insulating film 43 is etched back by reactive ion etching to expose the insulating layer 45, and the lower electrode 32 is exposed at the bottom portion of the transistor hole TH.

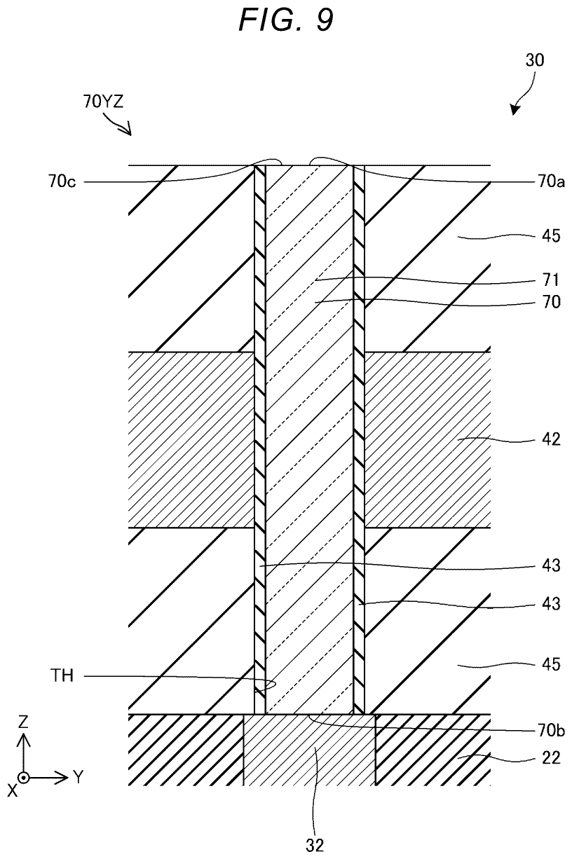

Next, as shown in FIG. 9, the film of the oxide semiconductor layer 70 is formed on the inside of the transistor hole TH and the surface of the insulating layer 45 on the upper side by atomic layer deposition. Thereby, the oxide semiconductor layer 70 surrounded by the gate insulating film 43 is formed inside the transistor hole TH. Then, the upper surface 70c of the oxide semiconductor layer 70 exposed on the upper side and the surface of the insulating layer 45 on the upper side are subjected to chemical mechanical polishing.

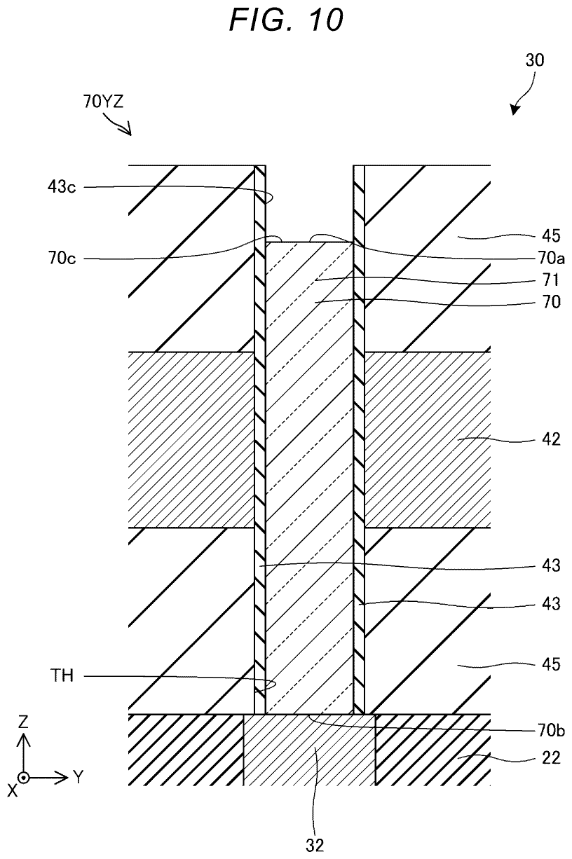

Next, as shown in FIG. 10, a part of the oxide semiconductor layer 70 on the upper side is removed by wet etching. Thereby, the upper surface 70c of the oxide semiconductor layer 70 is lowered downward to form a hole portion 43c.

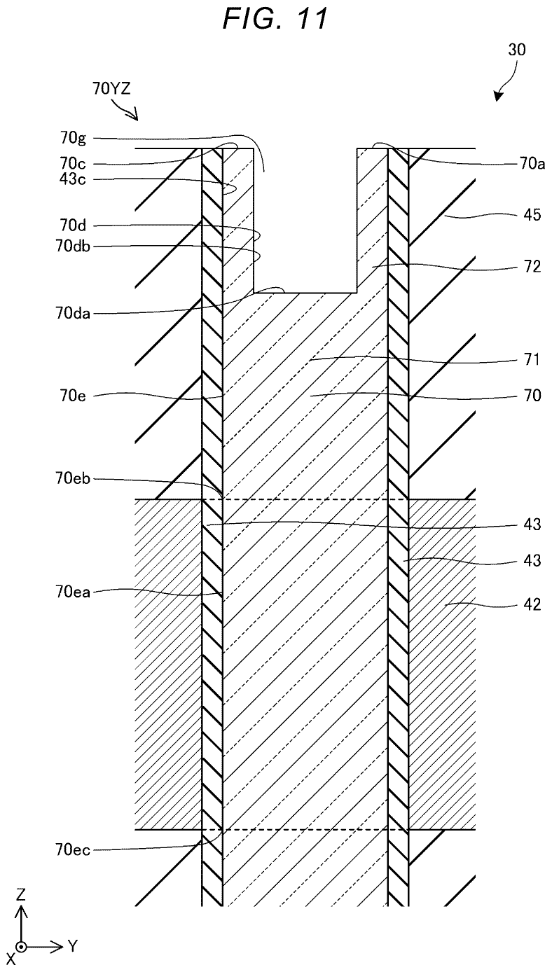

Next, as shown in FIG. 11, a thin film of the oxide semiconductor layer 70 is formed on the inner wall surface and the bottom surface of the hole portion 43c and on the surface of the insulating layer 45 on the upper side by atomic layer deposition or otherwise. Thereby, the hole portion 70g is formed. Then, by removing a part of the film of the oxide semiconductor layer 70 on the upper side by chemical mechanical polishing, the surface of the insulating layer 45 on the upper side is exposed, and the positions of the surface of the insulating layer 45 on the upper side and the upper surface 70c in the up-down direction are aligned.

Next, as shown in FIGS. 3 and 4, the metal oxide layer 50a, the barrier metal layer 50b, and the metal film 50c are stacked in this order on the upper surface 70c and the recessed surface 70d of the oxide semiconductor layer 70 and on the surface of the insulating layer 45 on the upper side. After a mask is formed by forming a film, applying a resist, exposing, developing, and releasing on the upper surface of the metal film 50c by a lithography method, the upper electrode 50 functioning as a landing pad is formed by etching.

### Second Embodiment

A semiconductor device 30B according to a second embodiment will be described. In the following second embodiment and later, the description of matters common to the first embodiment will be omitted, and only different points will be described. In particular, the same effects of the same configurations will not be successively described for each embodiment.

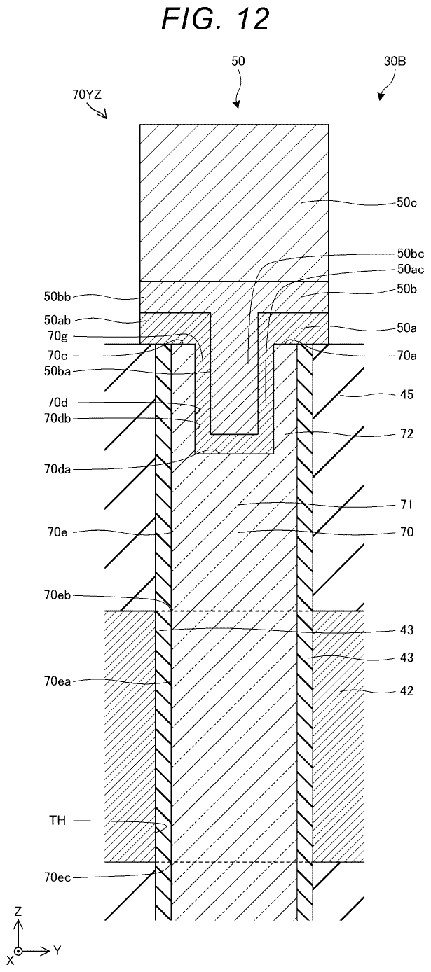

FIG. 12 is an enlarged cross-sectional view of the upper part of the semiconductor device 30B as viewed at the cross section 70YZ provided in the oxide semiconductor layer 70.

As shown in FIG. 12, the semiconductor device 30B according to the second embodiment is different from the semiconductor device 30 according to the first embodiment in that a part of the barrier metal layer 50b is provided in the hole portion 70g.

The barrier metal layer 50b in the upper electrode 50 has a facing surface 50ba (an example of a “first facing surface”) facing the upper surface 70c and the recessed surface 70d with the metal oxide layer 50a interposed therebetween.

In the present embodiment, the metal oxide layer 50a is formed as a thin film covering the upper surface 70c and the recessed surface 70d. Therefore, the hole portion 70g is not completely filled by the protruding portion 50ac, and a part of the hole portion 70g remains unfilled.

The barrier metal layer 50b is provided on the upper side of the metal oxide layer 50a. The barrier metal layer 50b has a thin film-like thin film portion 50bb that extends along the XY plane and a protruding portion 50bc that fills the remaining part of the hole portion 70g and protrudes downward from the thin film portion 50bb.

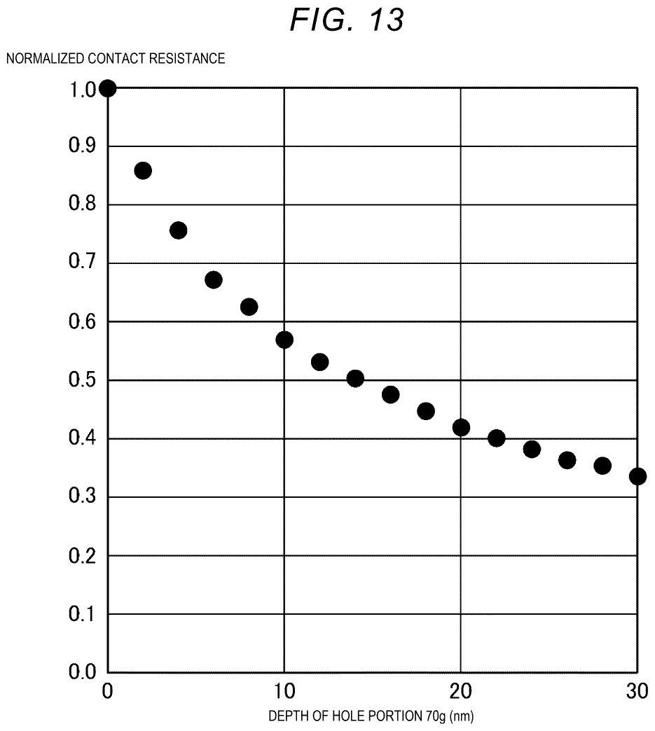

FIG. 13 is a view showing an example of a change in normalized contact resistance with respect to the depth of the hole portion 70g. The vertical axis indicates the normalized contact resistance. The horizontal axis indicates the depth of the hole portion 70g in units of “nm”.

As shown in FIG. 13, the normalized contact resistance is the sum of the contact resistance between the oxide semiconductor layer 70 and the metal oxide layer 50a and the contact resistance between the metal oxide layer 50a and the barrier metal layer 50b (also referred to as the sum of the contact resistances), normalized by the sum of the contact resistances when the depth of the hole portion 70g is 0 nm.

For example, by setting the depth of the hole portion 70g to 30 nm, the sum of the contact resistances can be reduced to approximately 33% of the sum of the contact resistances when the hole portion 70g is not provided.

### Third Embodiment

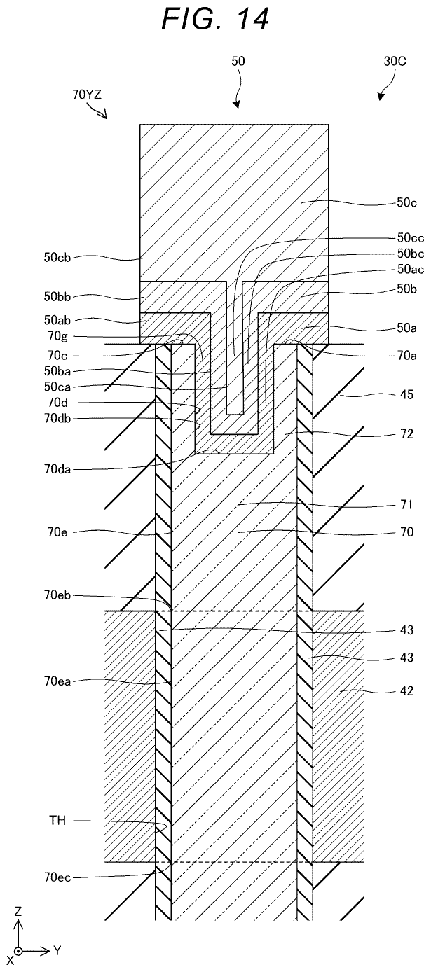

A semiconductor device 30C according to a third embodiment will be described. FIG. 14 is an enlarged cross-sectional view of the upper part of the semiconductor device 30C as viewed at the cross section 70YZ provided in the oxide semiconductor layer 70.

As shown in FIG. 14, the semiconductor device 30C is different from the semiconductor device 30B according to the second embodiment in that a part of the metal film 50c is provided in the hole portion 70g.

The metal film 50c in the upper electrode 50 has a facing surface 50ca (an example of a “second facing surface”) facing the upper surface 70c and the recessed surface 70d with the metal oxide layer 50a and the barrier metal layer 50b interposed therebetween.

In the present embodiment, the metal oxide layer 50a and the barrier metal layer 50b are formed as a thin film covering the upper surface 70c and the recessed surface 70d. Therefore, the hole portion 70g is not completely filled by the protruding portions 50ac and 50bc, and a part of the hole portion 70g remains unfilled.

The metal film 50c is provided on the upper side of the barrier metal layer 50b. The metal film 50c has a thin film-like thin film portion 50cb that extends along the XY plane and a protruding portion 50cc that fills the remaining part of the hole portion 70g and protrudes downward from the thin film portion 50cb.

### Fourth Embodiment

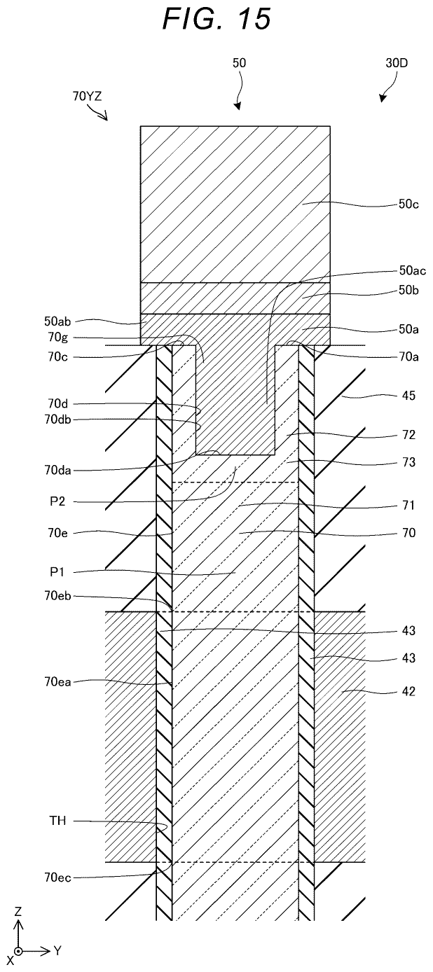

A semiconductor device 30D according to a fourth embodiment will be described. FIG. 15 is an enlarged cross-sectional view of the upper part of a semiconductor device 30D as viewed at the cross section 70YZ provided in the oxide semiconductor layer 70.

As shown in FIG. 15, the semiconductor device 30D according to the fourth embodiment is different from the semiconductor device 30 according to the first embodiment in that the composition of the oxide semiconductor layer 70 differs depending on the location.

In the fourth embodiment, the oxide semiconductor layer 70 comprises indium, oxygen, gallium, and zinc. The concentration of indium at a position P1 (“first position”) in the oxide semiconductor layer 70 is lower than the concentration of indium at a position P2 (“second position”) that is closer to the recessed surface 70d than the position P1. In some examples, oxide semiconductor layer 70 may comprise indium and oxygen and one of gallium and zinc.

In this example, a thin film of the oxide semiconductor layer 70 that is formed above the bottom portion of the hole portion 43c by atomic layer deposition after the hole portion 43c (see FIGS. 10 and 11) has been formed may be referred to as an electrode peripheral portion 73. The electrode peripheral portion 73 has a cup shape that is open upward.

The electrode peripheral portion 73 is formed inside the hole portion 43c in an atomic layer deposition process or otherwise by which the concentration of indium is set to be higher than the concentration of indium at the position P1.

As a result, a sufficient amount of carriers can be generated in the electrode peripheral portion 73 so that the electrode peripheral portion 73 can be used as a charge storage layer. Since the metal oxide layer 50a and the charge storage layer (electrode peripheral portion 73) are in contact with each other, the interface resistance can be reduced, and thus the current flowing through the oxide semiconductor layer 70 can be increased.

### Modification Example

The present disclosure is not limited to a configuration in which the concentration of indium at the position P1 is lower than the concentration of indium at the position P2. The oxide semiconductor layer 70 may comprise indium, gallium, zinc, and oxygen at the position P1 and then further comprise tin at the position P2. The oxide semiconductor layer 70 may comprise indium and oxygen and one of gallium and zinc at the position P1.

In this case, the electrode peripheral portion 73 may be formed inside the hole portion 43c in an atomic layer deposition process or the like in which indium, gallium, zinc, oxygen, and tin is deposited as the electrode peripheral portion 73.

As a result, a sufficient amount of carriers can be generated in the electrode peripheral portion 73 by incorporation of tin so that the electrode peripheral portion 73 can be used as a charge storage layer.

### Fifth Embodiment

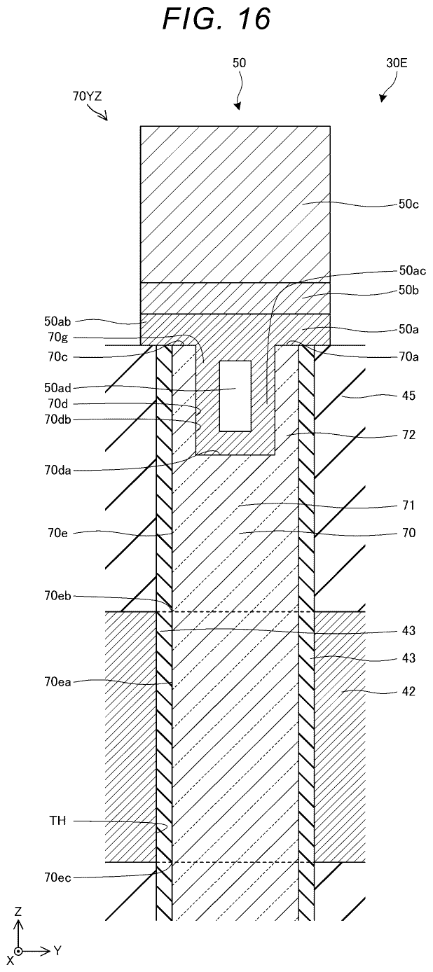

A semiconductor device 30E according to a fifth embodiment will be described. FIG. 16 is an enlarged cross-sectional view of the upper part of the semiconductor device 30E as viewed at the cross section 70YZ provided in the oxide semiconductor layer 70.

As shown in FIG. 16, the semiconductor device 30E according to the fifth embodiment is different from the semiconductor device 30 according to the first embodiment in that a cavity (void) is formed inside the upper electrode 50.

The upper electrode 50 includes a cavity portion 50ad at least a part of which is provided inside the hole portion 70g having the recessed surface 70d as an inner surface. In the fifth embodiment, the cavity portion 50ad is provided in the metal oxide layer 50a. All of the cavity portion 50ad is located inside the hole portion 70g in this example.

The cavity portion 50ad is formed, for example, by increasing a film formation speed of the metal oxide layer 50a.

Although a configuration in which the entire cavity portion 50ad is located inside the hole portion 70g is depicted, the present disclosure is not limited thereto. A part of the cavity portion 50ad may be located inside the hole portion 70g and the rest of the cavity portion 50ad may protrude upward from the hole portion 70g.

### Sixth Embodiment

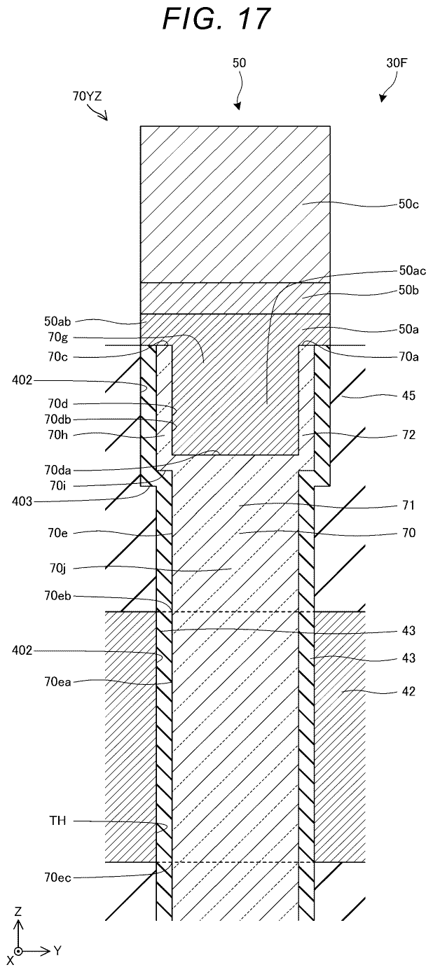

A semiconductor device 30F according to a sixth embodiment will be described. FIG. 17 is an enlarged cross-sectional view of the upper part of the semiconductor device 30F as viewed at the cross section 70YZ provided in the oxide semiconductor layer 70.

As shown in FIG. 17, the semiconductor device 30F according to the sixth embodiment is different from the semiconductor device 30 according to the first embodiment in that a step portion 70i is formed on the side surface 70e of the oxide semiconductor layer 70.

The oxide semiconductor layer 70 includes a small-diameter portion 70j and a large-diameter portion 70h located above the small-diameter portion 70j. The large-diameter portion 70h is connected to the small-diameter portion 70j at the step portion 70i. The recessed surface 70d is provided in the large-diameter portion 70h.

### Method for Manufacturing Semiconductor Device 30F

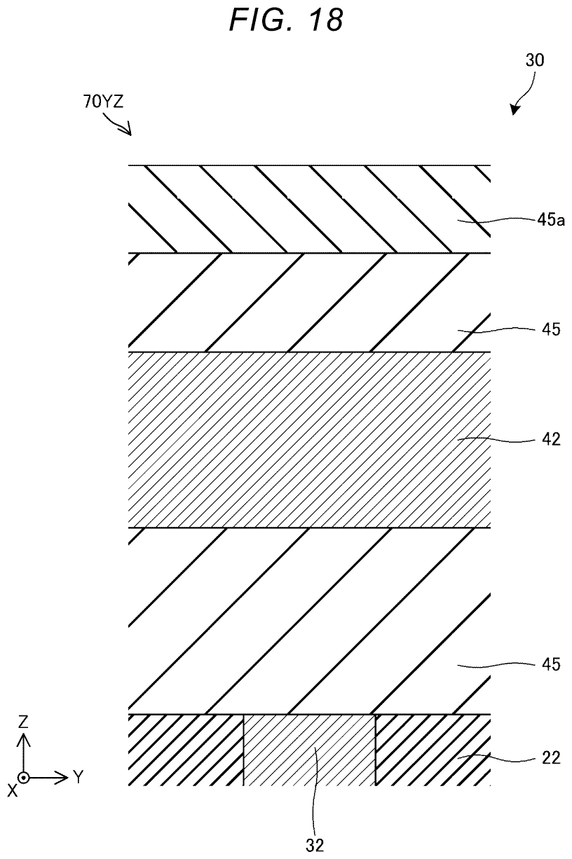

First, as shown in FIG. 18, an insulating layer 45a is stacked on the insulating layer 45. The insulating layer 45a comprises, for example, silicon and oxygen. Specifically, the insulating layer 45 and the insulating layer 45a are SiO₂. The rate of wet etching with respect to the insulating layer 45a is higher than the rate of wet etching with respect to the insulating layer 45.

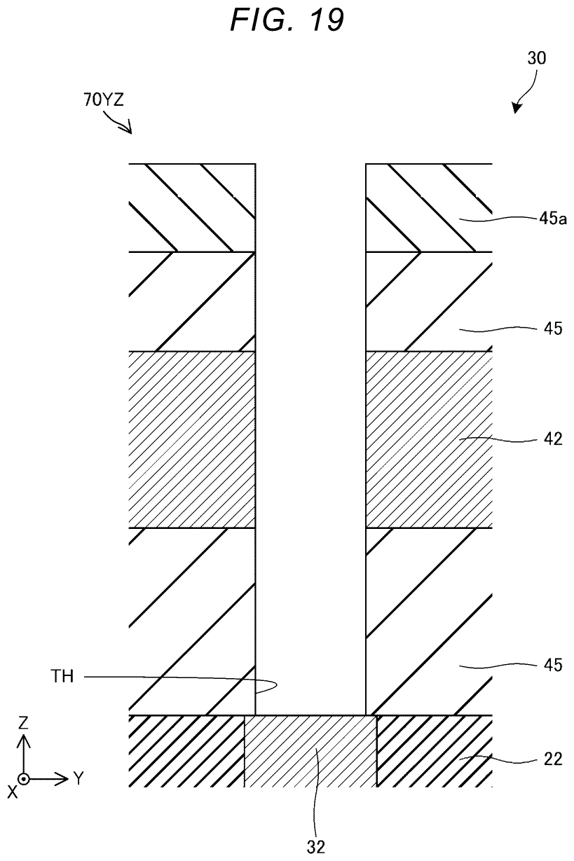

Next, as shown in FIG. 19, the transistor hole TH is formed by reactive ion etching and then cleaned.

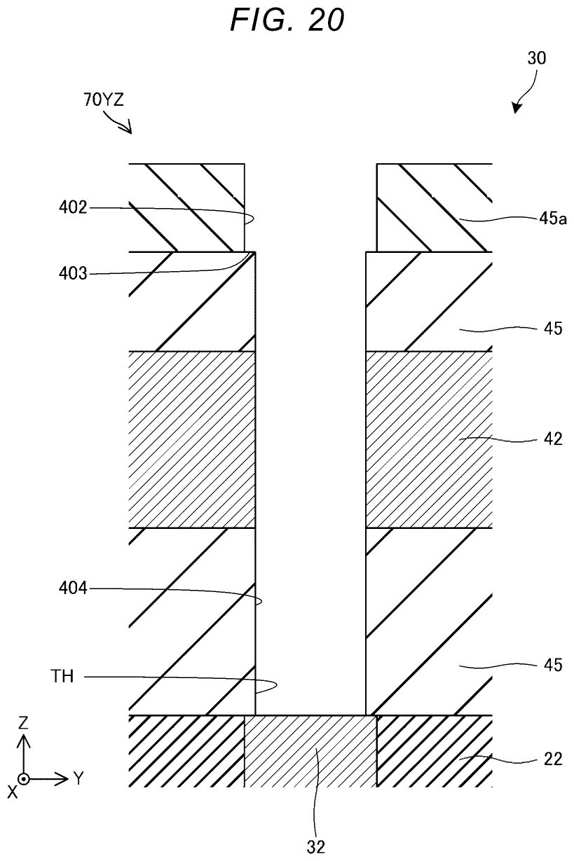

Next, as shown in FIG. 20, the diameter of a part of the transistor hole TH on the upper side is enlarged by, for example, wet etching. This occurs because the rate of wet etching of the insulating layer 45a is higher than the rate of wet etching of the insulating layer 45, and thus the amount of the insulating layer 45a removed is greater than the amount of the insulating layer 45 removed. Thereby, a transistor hole TH is formed which includes a small-diameter portion 404 and a large-diameter portion 402 connected to the small-diameter portion 404 at a step portion 403. The step portion 403 has an exposed surface facing upward at this point.

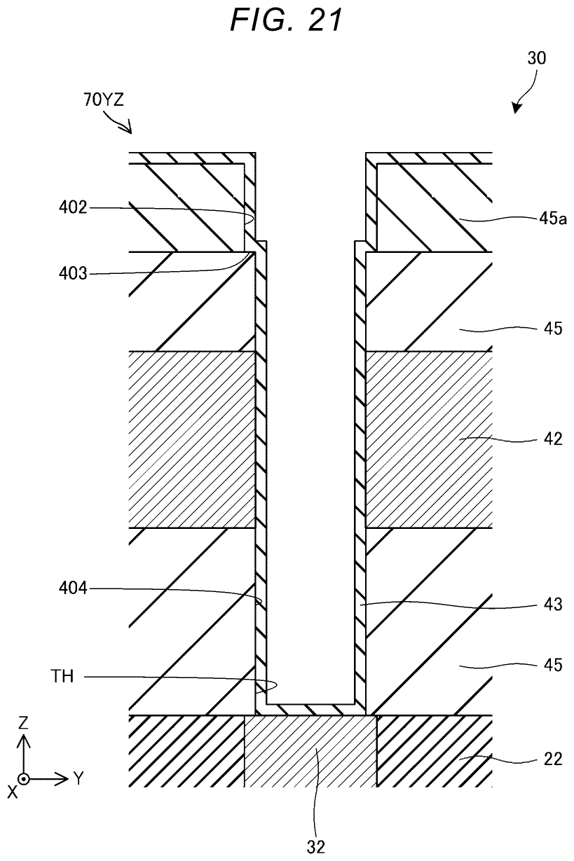

Next, as shown in FIG. 21, the gate insulating film 43 is formed on the inner wall surface and the bottom surface of the transistor hole TH and on the surface of the insulating layer 45a on the upper side.

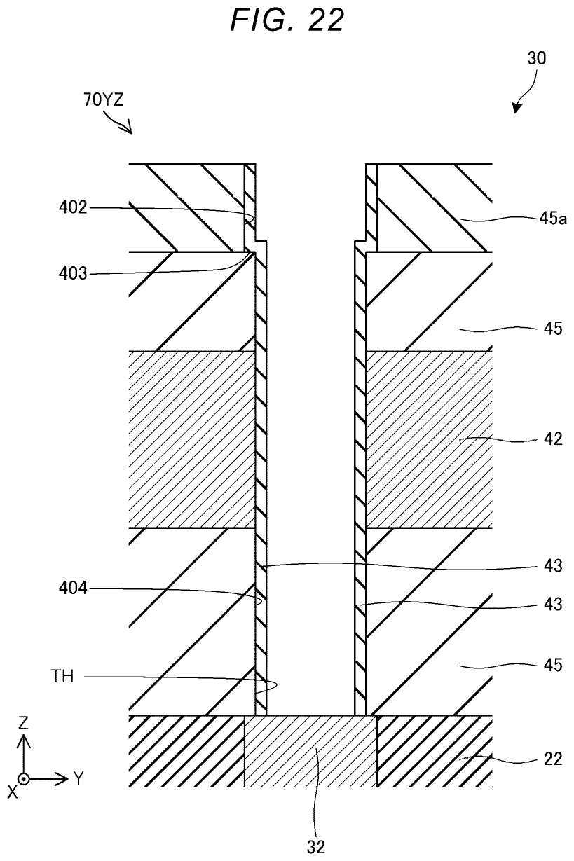

Next, as shown in FIG. 22, a part of the gate insulating film 43 is etched back by reactive ion etching to expose the insulating layer 45a, and the lower electrode 32 is exposed at the bottom portion of the transistor hole TH.

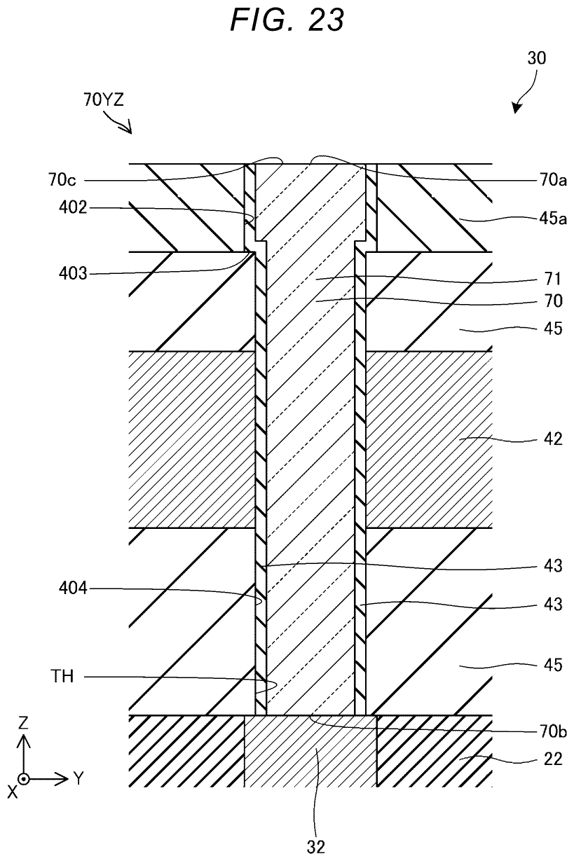

Next, as shown in FIG. 23, a film of the oxide semiconductor layer 70 is formed inside the transistor hole TH and on the surface of the insulating layer 45a on the upper side by, for example, atomic layer deposition. Thereby, the oxide semiconductor layer 70 surrounded by the gate insulating film 43 is formed inside the transistor hole TH. Then, the upper surface 70c of the oxide semiconductor layer 70 and the surface of the insulating layer 45 on the upper side, which are exposed upward, are subjected to chemical mechanical polishing.

Since the subsequent manufacturing steps are the same as those in FIGS. 10 and 11, a detailed description thereof will be omitted.

### Seventh Embodiment

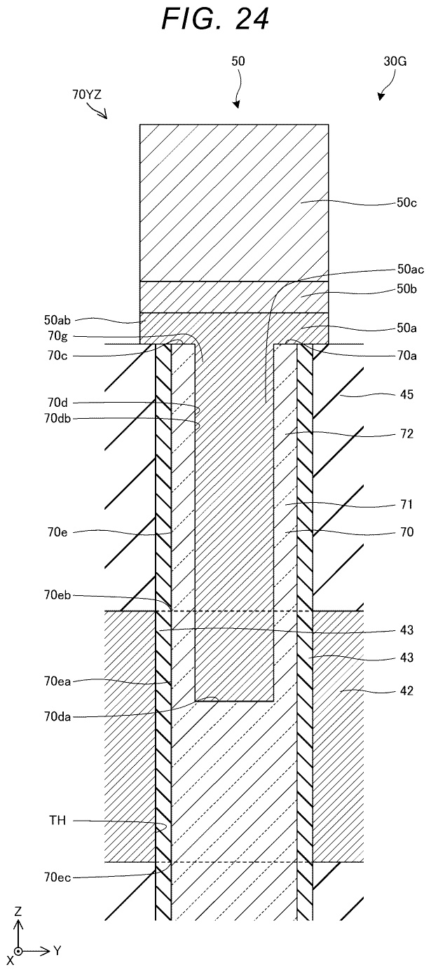

A semiconductor device 30G according to a seventh embodiment will be described. FIG. 24 is an enlarged cross-sectional view of the upper part of the semiconductor device 30G as viewed at the cross section 70YZ provided in the oxide semiconductor layer 70.

As shown in FIG. 24, the semiconductor device 30G according to the seventh embodiment is different from the semiconductor device 30 according to the first embodiment in that a part of the hole portion 70g on the lower side is surrounded by conductive layer 42.

An end portion of the recessed surface 70d on the lower side, that is, the bottom surface 70da is located below the end portion 70eb of the facing surface 70ea on the upper side. In the seventh embodiment, the hole portion 43c is formed deep enough that the bottom portion of the hole portion 43c is surrounded by the conductive layer 42 (see FIG. 10). Thereby, a hole portion 70g is formed in which the bottom surface 70da is located below the end portion 70eb.

With such a configuration, the area of contact between the oxide semiconductor layer 70 and the upper electrode 50 can be increased. As a result, the parasitic resistance can be effectively reduced.

In addition, the high-resistance extension portion 71 can be replaced with the protruding portion 50ac having a low electric resistance, and the electric resistance of the extension portion 71 can be reduced. Thereby, the current flowing through the oxide semiconductor layer 70 can be further increased.

In each example embodiment, a configuration in which the lower electrode 32 is electrically connected to the capacitor electrode 24 has been described, but the present disclosure is not limited thereto. In other examples, upper electrode 50 may be electrically connected to the capacitor electrode 24.

Although a configuration in which the bottom of the recessed surface 70d in the oxide semiconductor layer 70 is the substantially planar bottom surface 70da has been described, the present disclosure is not limited thereto. In other examples, the bottom of the recessed surface 70d may have another shape such as pointed, concave, or convex.

(a) A semiconductor device includes:
an oxide semiconductor extending in an up-down direction, having an annular upper surface, a recessed surface surrounded by the upper surface and recessed downward, a side surface, and a contact surface located below;
an insulating film surrounding the side surface of the oxide semiconductor;
a first electrode in contact with the contact surface of the oxide semiconductor;
a gate electrode facing the upper surface and a part of the side surface that is spaced apart from the contact surface, with the insulating film interposed therebetween; and
a second electrode in contact with the upper surface and the recessed surface of the oxide semiconductor.
   (b) A semiconductor device includes:
an oxide semiconductor having a recessed surface extending in an up-down direction and recessed downward, an upper surface surrounding the recessed surface, a side surface, and a contact surface located below;
an insulating film surrounding the side surface of the oxide semiconductor;
a first electrode in contact with the contact surface of the oxide semiconductor;
a gate electrode facing the upper surface and a part of the side surface that is spaced apart from the contact surface, with the insulating film interposed therebetween; and
a second electrode in contact with the recessed surface and the upper surface of the oxide semiconductor.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
an oxide semiconductor layer extending in an up-down direction, the oxide semiconductor layer having:
an annular upper surface with a recessed interior surface below the annular upper surface, the recessed interior surface being surrounded by an inner edge of the annular upper surface,
a bottom surface at an opposite end of the annular upper surface in the up-down direction, and
an outer peripheral side surface extending from the annular upper surface to the bottom surface;
an insulating film surrounding the outer peripheral side surface of the oxide semiconductor layer from the annular upper surface to bottom surface;
a first electrode in contact with the bottom surface of the oxide semiconductor layer;
a gate electrode facing a part of the outer peripheral side surface with the insulating film interposed therebetween, the part being spaced from the annular upper surface and the bottom surface of the oxide semiconductor layer; and
a second electrode in contact with the annular upper surface and the recessed interior surface of the oxide semiconductor layer.

2. The semiconductor device according to claim 1, wherein the recessed interior surface includes a substantially flat bottom surface on a lower side.

3. The semiconductor device according to claim 2, wherein the recessed interior surface has a cylindrical sidewall surface that extends upward from an outer edge of the flat bottom surface.

4. The semiconductor device according to claim 1, wherein the second electrode includes:
a first conductive layer in contact with the recessed interior surface and the annular upper surface, and
a second conductive layer on the first conductive layer and having a first facing surface that faces the recessed interior surface with the first conductive layer interposed therebetween.

5. The semiconductor device according to claim 4, wherein the second electrode further includes:
a third conductive layer on the second conductive layer and having a second facing surface that faces the recessed interior surface with the first conductive layer and the second conductive layer interposed therebetween.

6. The semiconductor device according to claim 5, wherein the third conductive layer comprises tungsten.

7. The semiconductor device according to claim 4, wherein the first conductive layer comprises a conductive oxide.

8. The semiconductor device according to claim 4, wherein the second conductive layer comprises titanium and at least one of oxygen and nitrogen.

9. The semiconductor device according to claim 8, wherein the second conductive layer further comprises a metal element in addition to titanium.

10. The semiconductor device according to claim 1, wherein the oxide semiconductor layer comprises oxygen and at least one of indium, gallium, aluminum, zinc, tin, titanium, tungsten, and molybdenum.

11. The semiconductor device according to claim 1, wherein
the oxide semiconductor layer comprises indium, oxygen, and at least one of gallium and zinc, and
a concentration of indium at a first position in the oxide semiconductor layer is lower than a concentration of indium at a second position closer to the recessed interior surface.

12. The semiconductor device according to claim 1, wherein the oxide semiconductor layer comprises, at a first position, indium, oxygen, and at least one of gallium and zinc, and, at a second position closer to the recessed interior surface, indium, oxygen, tin and at least one of gallium and zinc.

13. The semiconductor device according to claim 1, wherein a distance between the outer peripheral side surface and an interior sidewall surface of the recessed interior surface of the oxide semiconductor is greater than zero but less than 5 nm.

14. The semiconductor device according to claim 1, wherein the second electrode includes a cavity portion at least a part of which is in a position surrounded by the recessed interior surface.

15. The semiconductor device according to claim 1, wherein the recessed interior surface is in an upper end portion of the oxide semiconductor layer that is wider than a lower end portion of the oxide semiconductor layer.

16. The semiconductor device according to claim 15, wherein a sidewall surface of the recessed interior surface is above a portion of the outer peripheral side surface of the lower end portion of the oxide semiconductor layer.

17. The semiconductor device according to claim 15, wherein a bottom surface of the recessed interior surface is located at a position above the lower end portion of the oxide semiconductor layer.

18. The semiconductor device according to claim 1, wherein
the oxide semiconductor layer includes a small-diameter portion and a large-diameter portion that is connected to an upper portion of the small-diameter portion at a step portion, and
the recessed interior surface is in the large-diameter portion.

19. The semiconductor device according to claim 1, wherein a bottom surface of the recessed interior portion is at a position in the oxide semiconductor layer that faces the gate electrode with the insulating film interposed therebetween.

20. A semiconductor storage device, comprising:
a semiconductor device according to claim 1;
a first capacitor electrode connected to the first electrode or the second electrode;
a second capacitor electrode that faces the first capacitor electrode; and
a dielectric film between the first capacitor electrode and the second capacitor electrode.
